(19) United States
(12) Patent Application Publication
(10) Pub. No.: US 2002/0109231 A1
(43) Pub. Date: Aug. 15, 2002

(54) Composite structure of storage node and method of fabrication thereof

(75) Inventors: Chung-Ming Chu, Tainan Hsien (TW); Bor-Ru Sheu, Hsinchu (TW); Ming-Chung Chiang, Hsinchu Hsien (TW); Min-Chieh Yang, Kaohsiung (TW); Wen-Chung Liu, Taipei Hsien (TW); Jong-Bor Wang, Taipei (TW); Pai-Hsuan Sun, Kaohsiung (TW)

Correspondence Address: Richard P. Berg, Esq, c/o LADAS & PARRY, Suite 2100, 5670 Wilshire Boulevard, Los Angeles, CA, 90036-5679, US

(73) Assignee: Winbond Electronics Corp.

(21) Appl. No.: 09/885,209

(22) Filed: Jun. 20, 2001

(30) Foreign Application Priority Data
Feb. 15, 2001 (TW) 90103387

(51) Int. Cl. H01L 23/48; H01L 23/52; H01L 29/40

(52) U.S. Cl. 257/758

(57) ABSTRACT

A capacitor formed on a conductive plug of a semiconductor substrate has a composite storage node, wherein a Ru conductive layer covers the conductive plug and a conductive oxide layer with a perovskite structure covers the Ru conductive layer. A capacitor dielectric layer covers the composite storage node. An electrode layer covers the capacitor dielectric layer.

### BACKGROUND OF THE INVENTION

1. Field of the Invention

The present invention relates to a composite structure of storage node and a method of fabrication thereof. More particularly, the present invention relates to a storage node having a perovskite structure and a Ruthenium (Ru) conductive layer and a method of fabricating thereof.

2. Description of the Related Art

For improving the integration and performance of semiconductor devices, attempts are made to employ materials having a perovskite structure to form a capacitor. A ferroelectric film having the perovskite structure, such as PZT (lead zirconate titanate) or SBT (strontium bismuth tantalate) is used to form a capacitor storage for nonvolatile RAM. A dielectric film having the perovskite structure and high dielectric constant (high-k), such as BST (BaSrTiO₃) or STO (SrTiO₃), is used to form a capacitor dielectric film for very high integration DRAM. The material of a storage node is selected from metallic materials, such as Pt (Platinum), Ru (Ruthenium) or Ir (Iridium), and alternatively a conductive oxide having the perovskite structure, such as SrRuO₃, BaRuO₃, (Ba,Sr)RuO₃, RuO₂, or IrO₂.

There are advantages to employ the conductive oxide having the perovskite structure to form the storage node. First, since the conductive oxide and the high-k dielectric film have the same perovskite structures and matched lattice constants, the activity energy during the nucleation of the high-k dielectric film is lowered and thus the process temperature during depositing the high-k dielectric film is reduced. Also, a local heter-epitaxial growth is formed to increase the crystallization characteristics of the high-k dielectric film. Second, the matched lattice constants lower the interface stress between the conductive oxide and the high-k dielectric film, and therefore defects caused by interfacial stress are avoided. Third, the conductive oxide having the perovskite structure serves as a vacancy sink, which effectively decreases the concentration of oxygen vacancies on the interface and further suppresses the leakage current of the capacitor dielectric film. Fourth, as disclosed in public documents, using the conductive oxide to form the capacitor storage and the storage node, the problems of dielectric constant of the capacitor, leakage current and reliability are effectively solved.

With regard to the conductive oxide having the perovskite structure, SrRuO₃ achieves better flatness and has better thermal reliability, thereby using SrRuO₃ to form the storage node obtains preferred characteristics in capacitance. However, since SrRuO₃ is an oxide that must be formed in an oxygen atmosphere at high temperatures (reaching 500˜600° C.), an oxidization effect is found on a plug that contacts SrRuO₃, resulting in an increase in contact resistance. Seeking to solve this problem, there have been attempts to form a barrier layer between the plug and SrRuO₃. In the 1999 IEDM document, K. Hieda (Toshiba) discloses a barrier layer of TiAlN between the plug and SrRuO₃. As shown in FIG. 1, above a bit line 10, a capacitor having the perovskite structure includes a storage node 12 of conductive oxide with the perovskite structure, a high-k capacitor dielectric film 14, and a capacitor storage 16 of a ferroelectric film. A polysilicon plug 18 is positioned below the storage node 12, and the bottom of the polysilicon plug 18 is electrically connected to a source/drain region 6 between two gate electrodes 8. In addition, a TiAlN barrier layer 19 is embedded between the storage node 12 and the polysilicon plug 18. However, during the formation of the TiAlN barrier layer 19, TiAlN has bad thermal performance in oxygen atmosphere, thus an oxide layer about hundreds of angstroms thick is formed at 600° C. The oxide layer may cause an increase in the contact resistance between the TiAlN barrier layer 19 and the storage node 12. Moreover, the process of embedding the TiAlN barrier layer 19 is certainly complicated and greatly increases production costs.

In another published document, Kuo-Shung Liu discloses an Ru conductive layer formed at the bottom of SrRuO₃ so as to construct a structure of PLZT(lead lanthanum zirconate titanate)/SrRuO₃/Ru/substrate. The Ru conductive layer is employed to restrain the diffusion between PLZT and SrRuO₃ and modify the remaining polarization (Pr) character of PLZT. Yet, the reason for of the diffusion is not explained. In the 1999 IECS document, Eun-Sunk Choi discloses a structure of RuO₂/Ru/polysilicon, which maintains the thermal stability at 800° C. It is believed that the RuO₂/Ru structure is suitable for use in the barrier layer.

### SUMMARY OF THE INVENTION

The present invention is a composite storage node, laminated by a conductive oxide, such as SrRuO₃, BaRuO₃, and (Ba,Sr)RuO₃, and a Ru conductive layer, wherein a RuO₂/Ru structure, serving as a barrier layer, is formed during deposit of the conductive oxide. The present invention also provides a method of fabricating the composite storage node.

The present invention provides a capacitor on a conductive plug of a semiconductor substrate. On the conductive plug, a composite storage node has a Ru conductive layer covering the conductive plug and a conductive oxide layer with a perovskite structure covering the Ru conductive layer. A capacitor dielectric layer is covering the composite storage node. An electrode layer is covering the capacitor dielectric layer.

The present invention provides a method of fabricating a capacitor on a semiconductor substrate that has a first insulating layer and a conductive plug embedded in the first insulating layer. A second insulating layer and a third insulating layer are sequentially formed on the exposed surface of the semiconductor substrate. Then, the third insulating layer and the second insulating layer are patterned to form a trench for exposing the conductive plug. Next, a Ru conductive layer and a conductive oxide layer with a perovskite structure are sequentially formed on the exposed surface of the semiconductor substrate. By removing the Ru conductive layer and the conductive oxide layer positioned outside the trench, the remaining part of the Ru conductive layer and the conductive oxide layer inside the trench serves as a concave type of composite storage node. Next, a capacitor dielectric layer and an electrode layer are sequentially formed on the composite storage node.

The present invention provides another method of fabricating a capacitor on a semiconductor substrate that has a first insulating layer and a conductive plug embedded in the first insulating layer. A second insulating layer having a trench is formed on the semiconductor substrate for exposing the conductive plug. Then, a Ru conductive pedestal is formed on the exposed surface of the conductive plug. Next, a conductive oxide layer with a perovskite structure is formed on the surface of the Ru conductive pedestal, wherein the Ru conductive pedestal and the conductive oxide layer serves as a pedestal type of composite storage node. Next, a capacitor dielectric layer and an electrode layer are sequentially formed on the composite storage node.

Accordingly, it is a principle object of the invention to provide a composite storage node by fabricating the conductive oxide on the Ru conductive layer.

It is another object of the invention to provide a concave type of composite storage node Yet another object of the invention is to provide a pedestal type of composite storage node.

It is a further object of the invention to provide a RuO₂/Ru structure on the conductive plug.

These and other objects of the present invention will become readily apparent upon further review of the following specification and drawings.

### BRIEF DESCRIPTION OF THE DRAWINGS

FIG. 1 depicts a barrier layer of TiAlN between the plug and SrRuO₃ according to the prior art.

FIG. 2 depicts the crystallization of SrRuO₃ on substrates of various materials.

FIG. 3 depicts a cross-sectional diagram of a conductive plug according to the present invention.

FIGS. 4A to 4E depict a method of forming a concave type of composite storage node in the first embodiment of the present invention.

FIGS. 5A to 5E depict a method of forming a pedestal type of composite storage node in the second embodiment of the present invention.

FIGS. 6A and 6B depict cross-sectional diagrams of a capacitor according to the third embodiment of the present invention.

FIGS. 7A and 7B depict cross-sectional diagrams of a capacitor according to the fourth embodiment of the present invention.

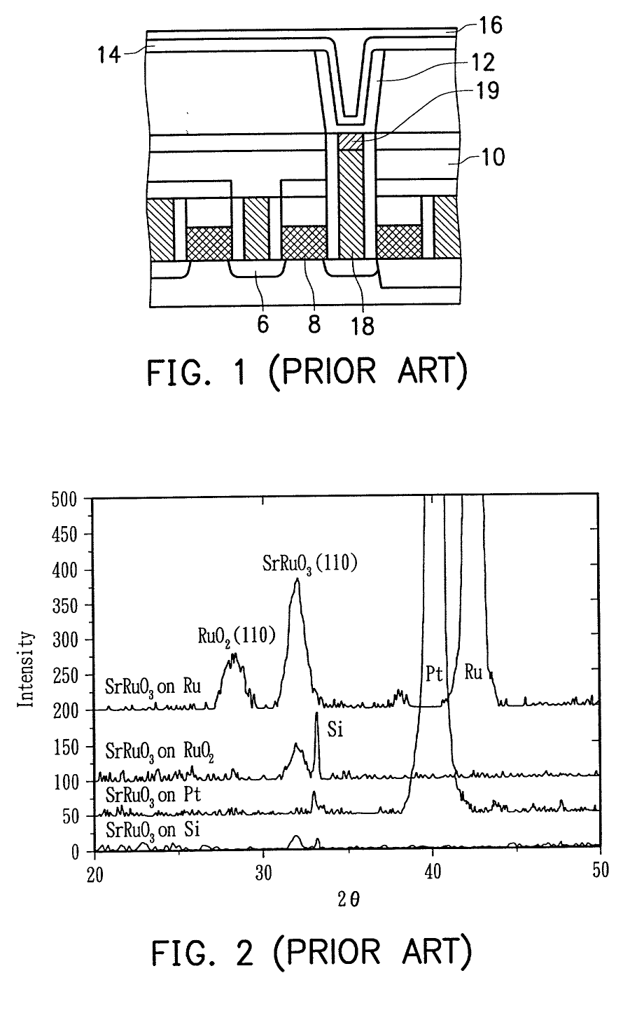

Similar reference characters denote corresponding features consistently throughout the attached drawings.

### DETAILED DESCRIPTION OF THE PREFERRED EMBODIMENTS

In proof of the crystallization of SrRuO₃, an SrRuO₃ film is formed on substrates of various materials, such as SiO₂/Si, Pt/SiO₂/Si, Ru/SiO₂/Si, and RuO₂/SiO₂/Si. As shown in FIG. 2, the best appearance of the crystallization of SrRuO₃ is found on the Ru conductive layer, the next best appearance is found on the RuO₂ layer, and amorphous appearance is found on the Pt conductive layer and the SiO₂ layer. Therefore, the Ru conductive layer and the RuO₂ layer are believed to increase the crystallization of the SrRuO₃ film. In addition, the process temperature of depositing the SrRuO₃ film on the Ru conductive layer is lower, and a RuO₂/Ru structure having thermal stability at 800° C. is found during depositing the SrRuO₃ film.

Accordingly, in fabricating a composite storage node of the present invention, there is an attempt to form a conductive oxide, such as SrRuO₃, BaRuO₃, or (Ba,Sr)RuO₃ on a Ru conductive layer. The purpose of using the Ru conductive layer is to improve the crystallization of the conductive oxide, and improve the dielectric characteristics of a capacitor dielectric film formed in sequent processes. The other purpose is to decrease the process temperature of depositing the conductive oxide. Besides, since a RuO₂/Ru structure, formed during depositing the conductive oxide, can serve as a barrier layer, instead of depositing a barrier layer, the process cost is lowered.

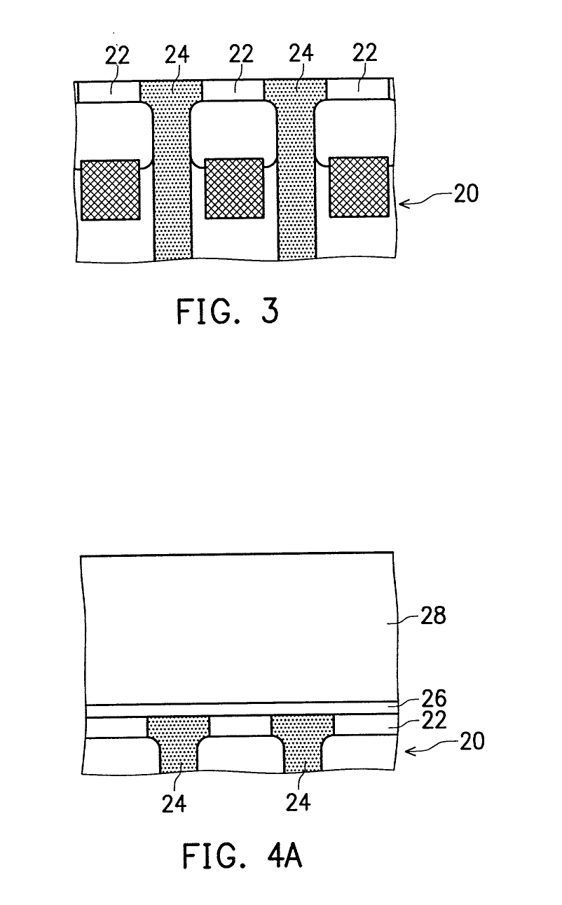

According to the RuO₂/Ru structure, two types of composite storage nodes, for example a concave type and a pedestal type, are provided on a plug of a semiconductor substrate. As shown in FIG. 3, a semiconductor substrate 20 has completed structures, such as gate electrodes, source/drain regions and bit lines. In fabricating a plurality of polysilicon plugs 24, a first insulating layer 22, of SiO₂ at a thickness of about 200˜1000 nm, is deposited on the semiconductor substrate 20. Then, using photolithography and etching processes, a plurality of contact windows of a diameter about 0.05˜0.15 m are patterned on the first insulating layer 22. Next, a polysilicon layer is deposited to fill the contact windows, and then the top surface of the polysilicon layer is leveled off with the top surface of the first insulating layer 22 by an etch back process, such as chemical mechanical polishing (CMP) method or reactive ion etch (RIE) method. Therefore, the remaining part of the polysilicon layer serves as the polysilicon plug 24.

Hereinafter, methods of forming a concave type of composite storage node and a pedestal type of composite storage node on the semiconductor substrate 20 are described respectively.

First Embodiment

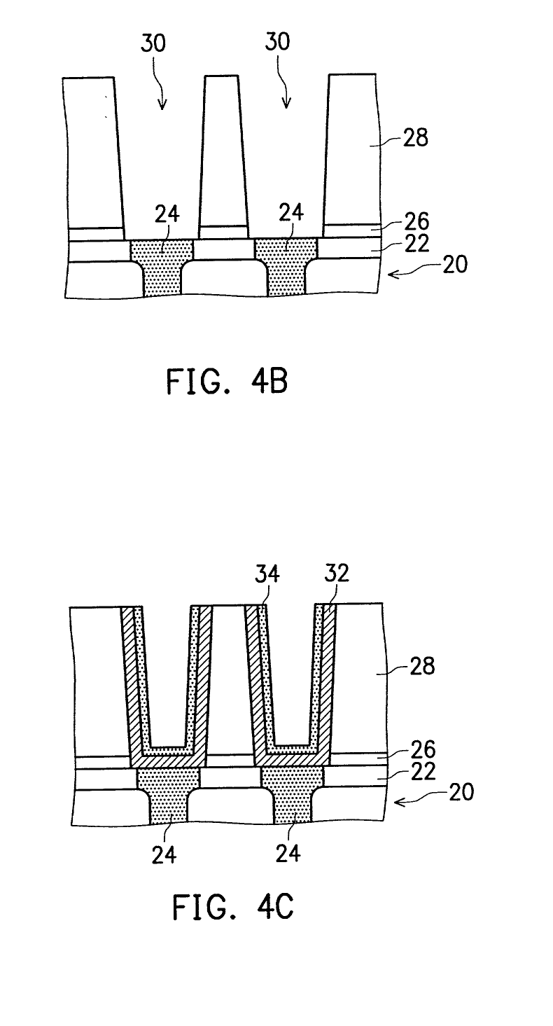

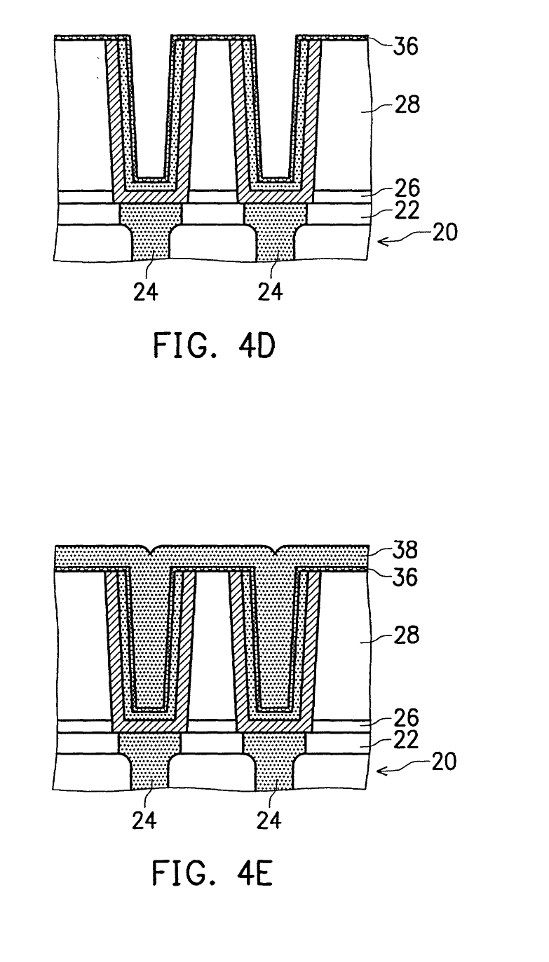

FIGS. 4A to 4E depict a method of forming a concave type of composite storage node according to the first embodiment of the present invention. As shown in FIG. 4A, a second insulating layer 26 and a third insulating layer 28 are sequentially formed on the exposed surface of the semiconductor substrate 20. The second insulating layer 26, serving as an etch stop layer, is preferably of silicon nitride or silicon-oxy-nitride of a thickness about 10˜100 nm. The third insulating layer 28 is preferably of silicon oxide of a thickness of about 300˜800 nm. As shown in FIG. 4B, using photolithography and etching processes, the third insulating layer 28 and the second insulating layer 26 are patterned to form a plurality of trenches 30, which exposes the polysilicon plugs 24 respectively. The diameter of the trench 30 is about 0.1˜0.18 m or 0.2˜0.45 m, and the inclination of the sidewall of the trench 30 is about 80˜90 degrees.

As shown in FIG. 4C, a Ru conductive layer 32 of a thickness about 10˜15 nm is uniformly deposited on the entire surface of the semiconductor substrate 20 so as to cover the sidewalls and bottoms of the trenches 30. Then, a conductive oxide layer 34 having a perovskite structure with a thickness of 10˜50 nm is uniformly deposited on the Ru conductive layer 32. Next, using a flattening technique such as CMP or RIE, the conductive oxide layer 34 and the Ru conductive layer 32 outside the trenches 30 are removed. Thus, the remaining part of the conductive oxide layer 34 and the Ru conductive layer 32 in each trench 30 serves as an individual composite storage node. Preferably, the conductive oxide layer 34 is SrRuO₃, BaRuO₃, or (Ba,Sr)RuO₃. For example, when SrRuO₃ is employed to form the conductive oxide layer 34, an SrRuO₃/Ru structure formed on the sidewall and bottom of the trench 30 serves as the concave type of the composite storage node, and a RuO₂/Ru structure formed during depositing of the conductive oxide layer 34 serves as a barrier layer.

As shown in FIG. 4D, a capacitor dielectric layer 36 about 10˜50 nm is uniformly deposited on the exposed surface of the semiconductor substrate 20. The capacitor dielectric film 36 maybe a ferroelectric film of PZT or SBT, or a high-k dielectric film of BST or SrTiO₃. As shown in FIG. 4E, an electrode layer 38, serving as a capacitor storage, is deposited on the capacitor dielectric layer 36 to fill the trenches 30. The electrode layer 38 of a thickness about 20˜100 nm may be of SrRuO₃, BaRuO₃, or (Ba,Sr)RuO₃.

Second Embodiment

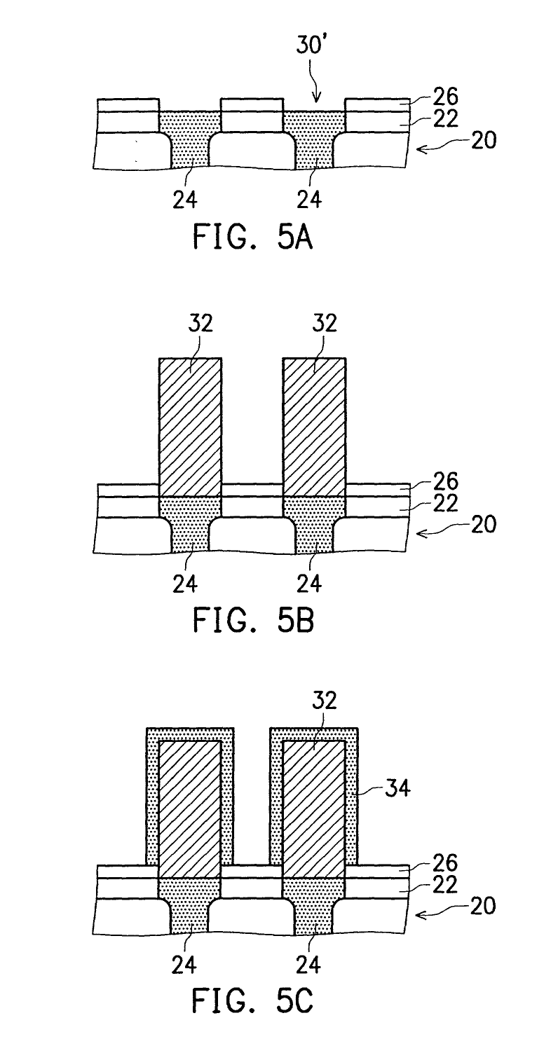

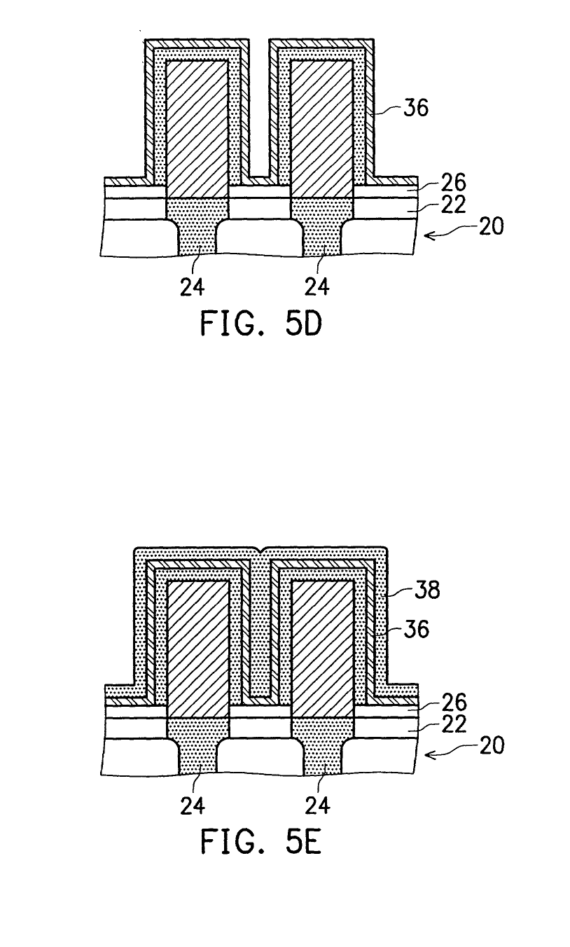

FIGS. 5A to 5E depict a method of forming a pedestal type of composite storage node according to the second embodiment of the present invention. As shown in FIG. 5A, a second insulating layer 26, of silicon nitride or silicon-oxy-nitride of a thickness about 10˜100 nm, is deposited on the exposed surface of the semiconductor substrate 20. Then, using the photolithography and etching processes, the second insulating layer 26 is patterned to form a plurality of shallow trenches 30′ for exposing the polysilicon plugs 24 respectively. Next, as shown in FIG. 5B, a Ru conductive layer 32 of a thickness about 300˜800 nm is deposited on the entire surface of the semiconductor substrate 20 to fill the shallow trenches 30′. Again using the photolithography and etching processes, the Ru conductive layer 32 is patterned to form a plurality of Ru conductive pedestals 32 on the polysilicon plugs 24 respectively.

As shown in FIG. 5C, a conductive oxide layer 34 having a perovskite structure with a thickness of 10˜50 nm is uniformly deposited on the exposed surface of the semiconductor substrate 20. Then, the conductive oxide layer 34 positioned on the second insulating layer 26 is removed, thus each of the Ru conductive pedestals and the remaining part of the conductive oxide layer 34 covering the Ru conductive pedestal serves as an individual composite storage node. The conductive oxide layer 34 may be SrRuO₃₁ BaRuO₃ or (Ba,Sr)RuO₃. For example, when SrRuO₃ is employ to form the conductive oxide layer 34, an SrRuO₃/Ru structure serves as the pedestal type of the composite storage node, and a RuO₂/Ru structure formed during depositing of the conductive oxide layer 34 serves as a barrier layer. Next, as shown in FIG. 5D, a capacitor dielectric layer 36 of a thickness about 10˜50 nm is uniformly deposited on the exposed surface of the semiconductor substrate 20. The capacitor dielectric film 36 may be a ferroelectric film of PZT or SBT, or a high-k dielectric film of BST or SrTiO₃. Then, as shown in FIG. 5E, an electrode layer 38, serving as a capacitor storage, is deposited on the capacitor dielectric layer 36 to fill the trenches 30. The electrode layer 38 of a thickness about 20˜100 nm may be SrRuO₃₁ BaRuO₃, or (Ba,Sr)RuO₃.

Third Embodiment

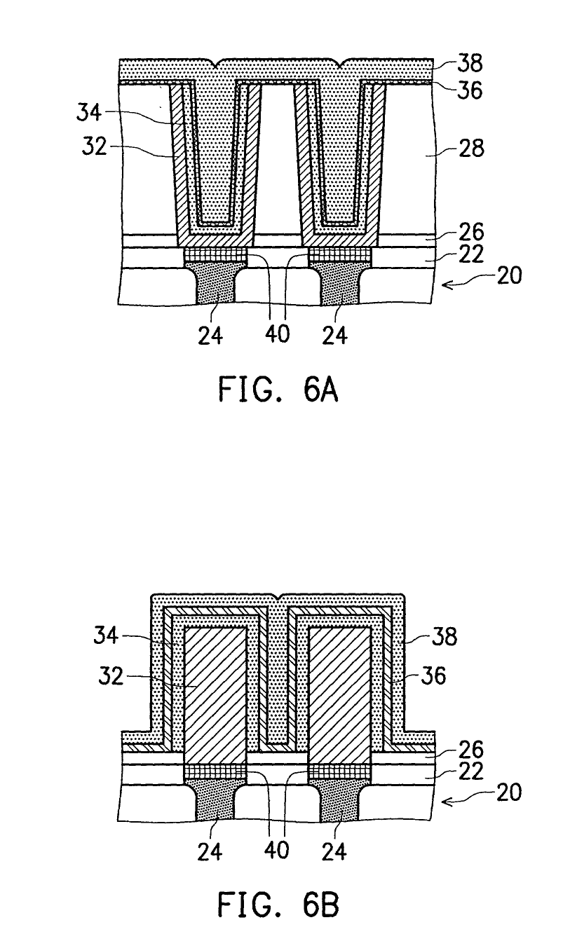

Referring to FIGS. 6A and 6B, in order to effectively avoid the oxygen diffusion effect and the polysilicon diffusion effect between the composite storage node and the polysilicon plug 24, an additional barrier layer 40 is provided between the composite storage node and the polysilicon plug 24 in the third embodiment of the present invention. The barrier layer 40 may be of TiN, TiAlN, TiSiN, or TaSiN. As shown in FIG. 6A, the barrier layer 40 is embedded between the concave type of composite storage node and the polysilicon plug 24. As shown in FIG. 6B, the barrier layer 40 is embedded between the pedestal type of composite storage node and the polysilicon plug 24.

Fourth Embodiment

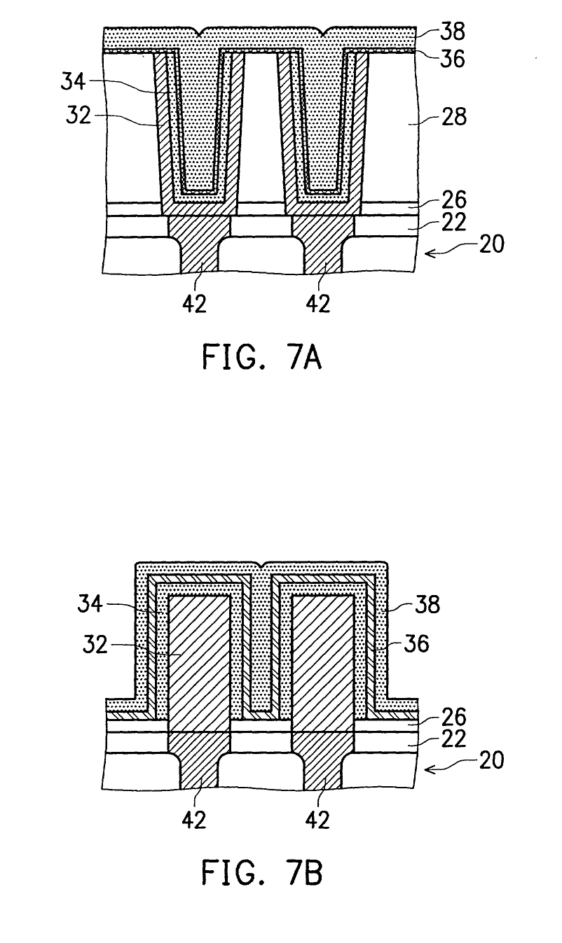

Referring to FIGS. 7A and 7B, in order to further avoid the oxygen diffusion effect and the polysilicon diffusion effect between the composite storage node and the polysilicon plug 24, a Ru conductive plug 42 is provided instead of the polysilicon plug 24 in the fourth embodiment of the present invention. Also, since the Ru conductive plug 42 is connected to the Ru conductive layer 32, the Ru conductive plug 42 compensates for the lack of thickness of the Ru conductive layer 32. As shown in FIG. 7A, the Ru conductive plug 42 underlies the concave type of composite storage node. As shown in FIG. 7B, the Ru conductive plug 42 underlies the pedestal type of composite storage node.

It is to be understood that the present invention is not limited to the embodiments described above, but encompasses any and all embodiments within the scope of the following claims.

What is claimed is:

1. A capacitor on a conductive plug of a semiconductor substrate, comprising:
a composite storage node which has a Ru conductive layer covering the conductive plug and a conductive oxide layer with a perovskite structure covering the Ru conductive layer;
a capacitor dielectric layer covering the composite storage node; and
an electrode layer covering the capacitor dielectric layer.

2. The capacitor according to claim 1, wherein the composite storage node is concave.

3. The capacitor according to claim 1, wherein the composite storage node is a pedestal type.

4. The capacitor according to claim 1, wherein the conductive oxide layer having the perovskite structure is SrRuO₃, BaRuO₃ or (Ba,Sr)RuO₃.

5. The capacitor according to claim 1, wherein the capacitor dielectric layer is PZT, SBT, BST or SrTiO₃.

6. The capacitor according to claim 1, wherein the electrode layer is SrRuO₃, BaRuO₃ or (Ba,Sr)RuO₃.

7. The capacitor according to claim 1, wherein the conductive plug is polysilicon.

8. The capacitor according to claim 7, further comprising a barrier layer between the conductive plug and the composite storage node.

9. The capacitor according to claim 1, wherein the conductive plug is Ru.

10. A method of fabricating a capacitor, comprising steps of:
providing a semiconductor substrate which has a first insulating layer and a conductive plug embedded in the first insulating layer;
forming a second insulating layer and a third insulating layer on the exposed surface of the semiconductor substrate sequentially;
patterning the third insulating layer and the second insulating layer to form a trench which exposes the conductive plug;
forming a Ru conductive layer and a conductive oxide layer with a perovskite structure on the exposed surface of the semiconductor substrate sequentially;
removing the Ru conductive layer and the conductive oxide layer positioned outside the trench, wherein the remaining part of the Ru conductive layer and the conductive oxide layer inside the trench serves as a concave type of composite storage node;
forming a capacitor dielectric layer on the composite storage node; and
forming an electrode layer on the capacitor dielectric layer.

11. The method according to claim 10, wherein the conductive plug is polysilicon.

12. The method according to claim 11, wherein the semiconductor substrate further comprises a barrier layer on the conductive plug.

13. The method according to claim 10, wherein the conductive plug is Ru.

14. The method according to claim 10, wherein the conductive oxide layer having the perovskite structure is SrRuO₃, BaRuO₃ or (Ba,Sr)RuO₃.

15. The method according to claim 10, wherein the capacitor dielectric layer is of PZT, SBT, BST or SrTiO₃.

16. The method according to claim 10, wherein the electrode layer is of SrRuO₃, BaRuO₃ or (Ba,Sr)RuO₃.

17. A method of fabricating a capacitor, comprising steps of:
providing a semiconductor substrate which has a first insulating layer and a conductive plug embedded in the first insulating layer;
forming a second insulating layer on the semiconductor substrate, wherein the second insulating layer has a trench for exposing the conductive plug;
forming a Ru conductive pedestal on the exposed surface of the conductive plug;
forming a conductive oxide layer with a perovskite structure on the surface of the Ru conductive pedestal, wherein the Ru conductive pedestal and the conductive oxide layer serves as a pedestal type of composite storage node;
forming a capacitor dielectric layer on the composite storage node; and
forming an electrode layer on the capacitor dielectric layer.

18. The method according to claim 17, wherein the conductive plug is polysilicon.

19. The method according to claim 17, wherein the semiconductor substrate further comprises a barrier layer on the conductive plug.

20. The method according to claim 17, wherein the conductive plug is Ru.

21. The method according to claim 17, wherein the conductive oxide layer having the perovskite structure is of SrRuO₃₁ BaRuO₃ or (Ba,Sr)RuO₃.

22. The method according to claim 17, wherein the capacitor dielectric layer is PZT, SBT, BST or SrTiO₃.

23. The method according to claim 17, wherein the electrode layer is SrRuO₃, BaRuO₃ or (Ba,Sr)RuO₃.
